(19) United States
(12) Patent Application Publication
(10) Pub. No.: US 2021/0057622 A1
(43) Pub. Date: Feb. 25, 2021

(54) LIGHT EMITTING DEVICE PACKAGE STRUCTURE AND MANUFACTURING METHOD THEREOF

(71) Applicant: Unistars Corporation, Zhudong Township (TW)

(72) Inventors: Tien-Hao Huang, New Taipei City (TW); Cheng-Kang Ku, Zhubei City (TW)

(21) Appl. No.: 16/590,396

(22) Filed: Oct. 2, 2019

(30) Foreign Application Priority Data
Aug. 23, 2019 (TW) 108130136

(51) Int. Cl. H01L 33/60; H01L 25/075; H01L 33/48; H01L 33/54; H01L 33/50

(52) U.S. Cl. CPC H01L 33/60; H01L 25/0753; H01L 33/483; H01L 2933/0058; H01L 33/502; H01L 2933/0033; H01L 2933/005; H01L 33/54

(57) ABSTRACT

A light emitting device package structure includes a substrate, a plurality of light emitting chips, a diffusion glue layer, a patterned masking colloid, and a transparent protective layer. The substrate has a bearing surface. The p light emitting chips are arranged and disposed on the bearing surface and electrically connected to the substrate. The light emitting chips compose an arrangement pattern. The diffusion glue layer is disposed on the bearing surface and covers the light emitting chips. The patterned masking colloid is formed on the diffusion glue layer. The patterned masking colloid at least corresponds to the arrangement pattern of the plurality of light emitting chips and is located directly above the plurality of light emitting chips. The transparent protective layer is disposed on the diffusion glue layer and covers the patterned masking colloid. A manufacturing method of a light emitting element package structure is also provided.

### FIELD OF THE INVENTION

The present invention relates to a package structure, and more particularly to a light emitting device package structure and a manufacturing method thereof.

### BACKGROUND OF THE INVENTION

In a conventional chip, COB LED is directly packaged as a point-light source, and the illumination thereof is uneven. Thus, glare may happens when the point-light source is applied to a light panel, so an additional optical fixture is necessary, such as a uniformity lighting plate or a uniformity lighting fixture to achieve a uniform light effect. As a result, the production cost is high.

Further, in a convention patterned surface-light source, a sticker is used to make a pattern and the pattern is attached to the appearance of the lamp or the LED light source module to achieve a patterning effect. However, the patterned surface-light source must use more LED chips to achieve the patterning effect and use a large amount of diffusion glue to achieve the uniformity lighting effect, so the thickness is large and the manufacturing cost is high.

### SUMMARY OF THE INVENTION

The invention provides a light emitting device package structure and a manufacturing method thereof, wherein the light emitting device package structure can achieve a uniform light effect, and effectively solve the uncomfortableness and the glare caused by human eyes directly looking at the light source.

The invention provides a light emitting device package structure, which includes a substrate, a plurality of light emitting chips, a diffusion glue layer, a patterned masking colloid, and a transparent protective layer. The substrate has a bearing surface. The plurality of light emitting chips is arranged and disposed on the bearing surface and electrically connected to the substrate. The plurality of light emitting chips has an arrangement pattern. The diffusion glue layer is disposed on the bearing surface and covers the plurality of light emitting chips. The patterned masking colloid is formed on the diffusion glue layer. The patterned masking colloid at least corresponds to the arrangement pattern of the plurality of light emitting chips and is located directly above the plurality of light emitting chips. The transparent protective layer is disposed on the diffusion glue layer and covers the patterned masking colloid.

In one embodiment of the present invention, the light emitting device package structure further includes a supporting retaining wall disposed on the bearing surface and surrounding the plurality of light emitting chips. The diffusion glue layer and the transparent protective layer are formed within a region surrounded by the supporting retaining wall.

In one embodiment of the present invention, a material of the supporting retaining wall includes a white silicone glue material, and a material of the transparent protective layer includes a transparent silicone glue material.

In one embodiment of the present invention, the light emitting device package structure further includes a patterned retaining wall colloid formed on the diffusion glue layer to block the patterned masking colloid. The transparent protective layer covers the patterned retaining wall colloid.

In one embodiment of the present invention, the patterned masking colloid is selected from a group consisting of a black silicone glue material, and the patterned retaining wall colloid is selected from a group consisting of a white silicone glue material and a black silicone glue material.

In one embodiment of the present invention, a coverage area of the patterned masking colloid is larger than an area of the arrangement pattern.

In one embodiment of the present invention, the substrate is selected from a group consisting of a flexible substrate, a glass fiber substrate, a resin substrate, a metal substrate, a ceramic substrate, and a plastic substrate.

In one embodiment of the present invention, the plurality of light emitting chips includes a monochromatic optical chip or is composed of a monochromatic optical chip and a phosphor layer thereon.

The invention provides a manufacturing method of a light emitting element package structure, which includes: disposing a plurality of light emitting chips on a bearing surface of a substrate and electrically connecting the plurality of light emitting chips to the substrate, wherein the plurality of light emitting chips has an arrangement pattern; forming a supporting retaining wall on the bearing surface, wherein the supporting retaining wall surrounds the plurality of light emitting chips; injecting a diffusion glue layer in a region surrounded by the supporting retaining wall, wherein the diffusion glue layer covers the plurality of light emitting chips and the bearing surface; forming a patterned masking colloid on the diffusion glue layer according to the arrangement pattern, so that the patterned masking colloid is located directly above the plurality of light emitting chips; and forming a transparent protective layer in the region surrounded by the supporting retaining wall to cover the diffusion glue layer and the patterned masking colloid.

In one embodiment of the present invention, the supporting retaining wall is formed by stacking a silicone glue material a plurality of times.

In one embodiment of the present invention, before the patterned masking colloid is formed, a patterned retaining wall colloid is formed on the diffusion glue layer to define a limited region of the patterned masking colloid.

In one embodiment of the present invention, the patterned masking colloid is selected from a group consisting of a black silicone glue material, and the patterned retaining wall colloid is selected from a group consisting of a white silicone glue material and a black silicone glue material.

In one embodiment of the present invention, the patterned masking colloid, the patterned retaining wall colloid, and the supporting retaining wall use different colors of silicone glue material.

In one embodiment of the present invention, the patterned masking colloid and the patterned retaining wall colloid are formed on the diffusion glue layer by coating, dispensing or screen printing.

In one embodiment of the present invention, the diffusion glue layer is formed by mixing diffusion powder and a silicone glue.

The invention uses a black silicone material to form a pattern directly above the light emitting chips and covering the light emitting chips. The light path is destroyed by the black silicone material, as such the light is laterally emitted and passes through the diffusion glue layer to achieve uniform light and exhibit visual effects. The use of the silicone glue manufacturing process to achieve graphics and packaging and to complete the packaging of the patterned surface-light source can increase the exterior viewing angle of the light emitting chips, eliminate the need for a uniformity lighting fixture and mechanism, and effectively solve the problem in which uncomfortable glare happens when human eyes looks directly at the light source.

### BRIEF DESCRIPTION OF THE DRAWINGS

The present invention will become more readily apparent to those ordinarily skilled in the art after reviewing the following detailed description and accompanying drawings, in which:

FIGS. 1A to 1F are schematic cross-sectional views of a light emitting device package structure according to an embodiment of the present invention, in which a flow of a manufacturing method a light emitting device package structure is illustrated;

FIG. 2 is a schematic view of a light emitting device package structure and light emission according to an embodiment of the present invention; and

FIG. 3 is a schematic view of a configuration of light emitting chips, a patterned masking colloid, and a preset pattern according to an embodiment of the invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

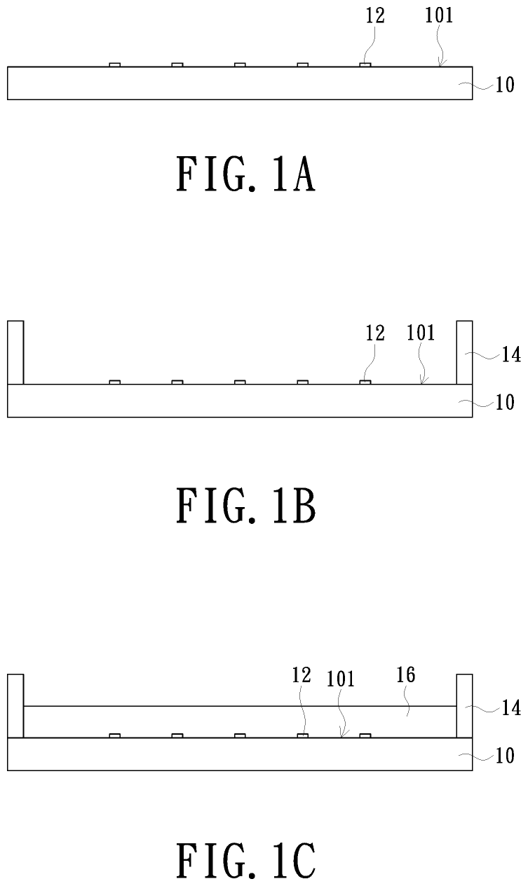

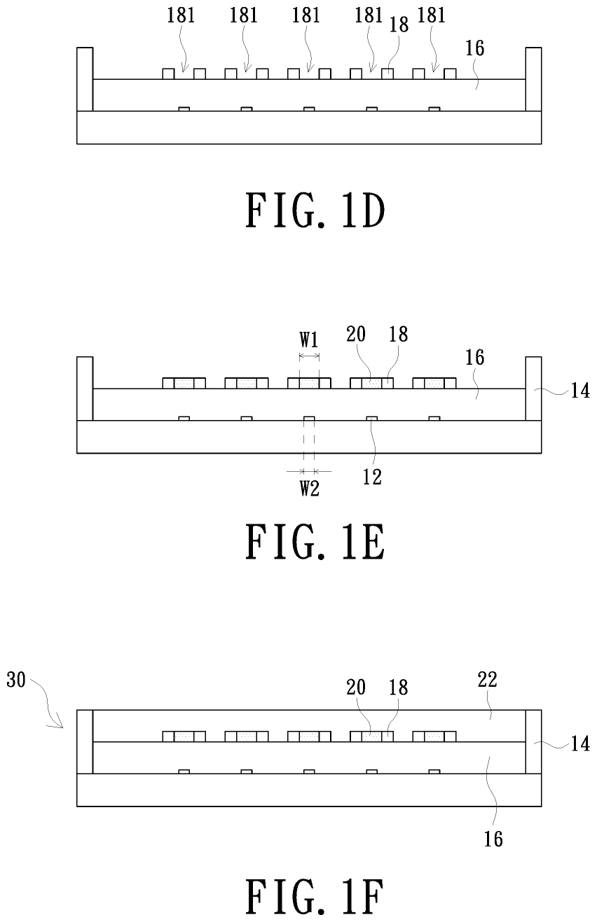

FIGS. 1A to 1F are schematic cross-sectional views of a light emitting device package structure according to an embodiment of the present invention, in which a process flow of a manufacturing method a light emitting device package structure is illustrated. As shown in FIG. 1A, a substrate 10 is provided. The substrate 10 has a bearing surface 101. A plurality of light emitting chips 12 is arranged and disposed on the bearing surface 101 of the substrate 10. The light emitting chips 12 are electrically connected to the substrate 10. The light emitting chips 12 have an arrangement pattern (not labeled) on the substrate 10. In one embodiment, the light emitting chip 12 is, for example, an LED chip and is disposed on the substrate 10 by a die bonding process. The type of the light emitting chip 12 is, for example, a horizontal LED chip, and the light emitting chip 12 is adhered to the substrate 10 by using a highly-conductive glue material, such as silver glue or silicone-based glue or the like, and the light emitting chip 12 is wire bonded. Alternatively, the type of the light emitting chip 12 is, for example, a flip chip, and the light emitting chip 12 is adhered to the substrate 10 by using solder paste. In one embodiment, the light emitting chip 12 includes a monochromatic optical chip, such as red, green or blue chip. Alternatively, the light emitting chip 12 is composed of a monochromatic optical chip and a phosphor layer thereon. For example, white light can be generated by using blue light emitted from a blue chip to excite the phosphor layer. In one embodiment, the substrate 10 is selected from a group consisting of a flexible substrate, a glass fiber substrate, a resin substrate, a metal substrate, a ceramic substrate, and a plastic substrate. P-N pads (not shown) are disposed on the substrate 10.

Thereafter, as shown in FIG. 1B, a supporting retaining wall 14 is formed on the bearing surface 101, and the supporting retaining wall 14 surrounds the light emitting chips 12. In one embodiment, the supporting retaining wall 14 is formed by stacking the silicone glue material a plurality of times, wherein the supporting retaining wall 14 formed in a manner of stacking the silicone glue material a plurality of times can surround to arbitrary different shapes on the substrate 10. In one embodiment, the material of the supporting retaining wall 14 includes a white silicone glue material. Thereafter, as shown in FIG. 1C, a diffusion glue layer 16 is injected into the region surrounded by the supporting retaining wall 14. The diffusion glue layer 16 covers the light emitting chips 12 and the bearing surface 101. The height of the diffusion glue layer 16 is lower than that of the supporting retaining wall 14. In one embodiment, the diffusion glue layer 16 is formed by mixing diffusion powder and silicone glue.

Thereafter, as shown in FIG. 1D, a patterned retaining wall colloid 18 is formed on the diffusion glue layer 16 to define a limited region 181 of a subsequent patterned masking colloid 20. Thereafter, as shown in FIG. 1E, a patterned masking colloid 20 is filled on the diffusion glue layer 16 and within the limited region 181 (shown in FIG. 1D) of the patterned retaining wall colloid 18, so that the patterned masking colloid 20 corresponds to the arrangement pattern of the light emitting chips 12 and is located directly above the light emitting chips 12. In one embodiment, the coverage area of the patterned masking colloid 20 is greater than the area of the arrangement pattern of the light emitting chips 12. For example, the coverage width W1 of the patterned masking colloid 20 is greater than 1.5 times the width W2 of the light emitting chip 12, that is, W1≥1.5 W2. In one embodiment, the patterned masking colloid 20 is selected from a group consisting of a black silicone glue material, and the patterned retaining wall colloid 18 is selected from a group consisting of a white silicone glue material and a black silicone glue material. In one embodiment, the patterned masking colloid 20, the patterned retaining wall colloid 18, and the supporting retaining wall 14 may use different colors of silicone glue material. Further, the patterned masking colloid 20 and the patterned retaining wall colloid 18 are formed on the diffusion glue layer 16 by coating, dispensing or screen printing.

Finally, as shown in FIG. 1F, a transparent protective layer 22 is formed in a region surrounded by the supporting retaining wall 14, so that the transparent protective layer 22 is disposed on the diffusion glue layer 16 and covers the patterned masking colloid 20 and the patterned retaining wall colloid 18. Accordingly, a light emitting device package structure 30 is manufactured. In one embodiment, the material of the transparent protective layer 22 includes a transparent silicone glue material.

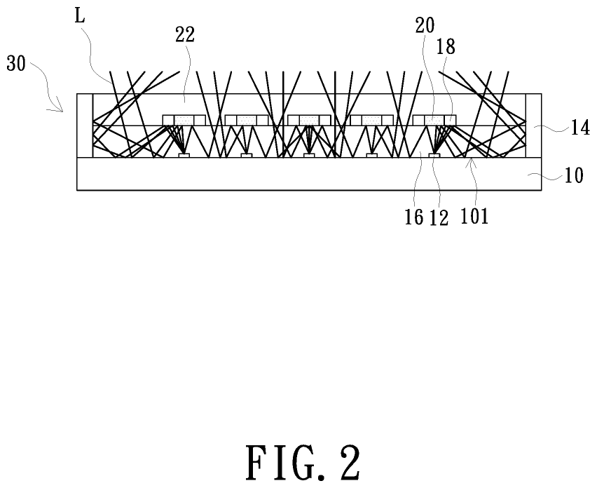

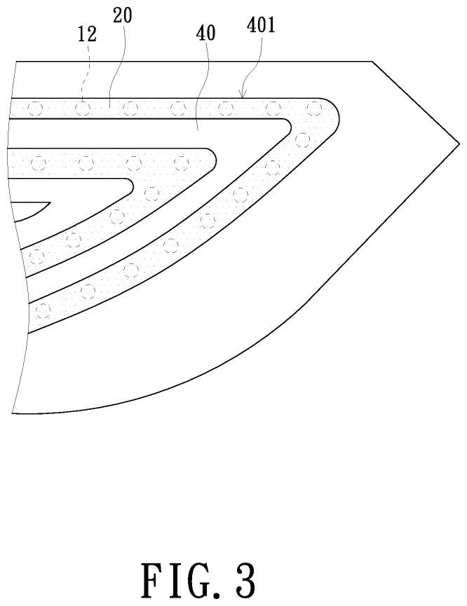

FIG. 2 is a schematic view of a light emitting device package structure and light emission according to an embodiment of the present invention. As shown in FIG. 2, the light emitting device package structure 30 includes a substrate 10, a plurality of light emitting chips 12, a supporting retaining wall 14, a diffusion glue layer 16, a patterned retaining wall colloid 18, a patterned masking colloid 20, and a transparent protective layer 22. The light emitting chips 12 are arranged and disposed on a bearing surface 101 of the substrate 10. The supporting retaining wall 14 is disposed on the bearing surface 101 and surrounds the light emitting chips 12. The diffusion glue layer 16 is disposed on the bearing surface 101 and covers the light emitting chips 12, wherein the supporting retaining wall 14 limits the injection range of the diffusion glue layer 16. The patterned masking colloid 20, such as a black silicone glue material, is disposed on the diffusion glue layer 16 and located directly above the light emitting chips 12. The peripheral side or both sides of the patterned masking colloid 20 is disposed with a patterned retaining wall colloid 18 to block the flow of the patterned masking colloid 20 during injection, so as to limit the patterned masking colloid 20 within a contour region (disclosed in subsequent FIG. 3) located in a preset pattern (disclosed in subsequent FIG. 3). The transparent protective layer 22 is disposed on the diffusion glue layer 16 and covers the patterned masking colloid 20 and the patterned retaining wall colloid 18. In one embodiment, the surface of the transparent protective layer 22 and the top of the supporting retaining wall 14 are at the same height.

Please continue to refer to FIG. 2. Since the (black) patterned masking colloid 20 is located directly above the light emitting chips 12, the travel direction of the forward straight light of the light emitting chip 12 can be changed by using the black patterned masking colloid 20 as the contour region and the reflective material of the preset pattern, as the light L is laterally emitted and passes through the diffusion glue layer 16 to achieve a uniform light and a graphical visual effect. The light emitting device package structure 30 can further exhibit the layered effect of the preset pattern when the patterned masking colloid 20, the patterned retaining wall colloid 18, and the supporting retaining wall 14 use different colors of the silicone glue material.

FIG. 3 is a schematic view of a configuration of light emitting chips, a patterned masking colloid, and a preset pattern according to an embodiment of the invention. As shown in FIG. 3, the light emitting chips 12 are, for example, spaced from each other by an interval and arranged along the contour region 401 of the preset pattern 40, wherein the interval may be equidistant or not equidistant. The black patterned masking colloid 20 may be formed in the contour region 401 of the preset pattern 40 as a contour of a preset pattern and cover the light emitting chips 12. When the light emitting chips 12 emit light, the light path is obstructed or destroyed by the black patterned masking colloid 20, as such the light is laterally emitted and passes through the diffusion glue layer 16 (labeled in FIG. 2) to achieve a uniform light and exhibit an illuminated preset pattern 40.

In the present invention, the patterning and packaging are achieved by a dispensing glue method to integrally form a patterned surface-light source package structure and increase the exterior viewing angle of the LED chip. As such, the cost of uniformity lighting fixture and mechanism is saved, compared to the conventional chip in which the LEDs are direct packaged. Furthermore, the uncomfortable and glare caused by the human eyes directly looking at the light source can effectively solved by changing the light source from a conventional point-light source to a surface-light source. On the other hand, conventionally when using a high-density light source as a surface-light source, more light emitting chips must be used, the chip spacing should be considered, and a large amount of diffusion glue must be used to interfere with the travel direction of light, which not only fails to achieve a uniformity light effect, but also limits the thickness of the silicone glue and cannot reduce the thickness, and therefore the manufacturing cost is increased due to the increase in the quantity of light emitting chips and diffusion glue. In contract, the light emitting device package structure of the embodiment uses a silicone glue material to achieve the package of a patterned surface-light source, wherein the black silicone glue material is patterned directly above the light emitting chips and covers the light emitting chips. Therefore, the light path is obstructed or destroyed by the black silicone glue material, as such the light is laterally emitted and passes through the diffusion glue layer to achieve uniform or evenly dispersed light and a graphical visual effect, thereby effectively reducing the amount of the light emitting chips and diffusion glue material.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A light emitting device package structure, comprising:
a substrate, having a bearing surface;
a plurality of light emitting chips, arranged and disposed on the bearing surface and electrically connected to the substrate, wherein the plurality of light emitting chips compose an arrangement pattern;
a diffusion glue layer, disposed on the bearing surface and covering the plurality of light emitting chips;
a patterned masking colloid, formed on the diffusion glue layer, wherein the patterned masking colloid at least corresponds to the arrangement pattern of the plurality of light emitting chips and is located directly above the plurality of light emitting chips; and
a transparent protective layer, disposed on the diffusion glue layer and covering the patterned masking colloid.

2. The light emitting device package structure according to claim 1, further comprising a supporting retaining wall disposed on the bearing surface and surrounding the plurality of light emitting chips, wherein the diffusion glue layer and the transparent protective layer are formed within a region surrounded by the supporting retaining wall.

3. The light emitting device package structure according to claim 2, wherein a material of the supporting retaining wall comprises a white silicone glue material, and a material of the transparent protective layer comprises a transparent silicone glue material.

4. The light emitting device package structure according to claim 1, further comprising a patterned retaining wall colloid formed on the diffusion glue layer to block the flow of the patterned masking colloid during injection, wherein the transparent protective layer covers the patterned retaining wall colloid.

5. The light emitting device package structure according to claim 4, wherein the patterned masking colloid is selected from a group consisting of a black silicone glue material, and the patterned retaining wall colloid is selected from a group consisting of a white silicone glue material and a black silicone glue material.

6. The light emitting device package structure according to claim 1, wherein a coverage area of the patterned masking colloid is larger than an area of the arrangement pattern.

7. The light emitting device package structure according to claim 1, wherein the substrate is selected from a group consisting of a flexible substrate, a glass fiber substrate, a resin substrate, a metal substrate, a ceramic substrate, and a plastic substrate.

8. The light emitting device package structure according to claim 1, wherein the plurality of light emitting chips comprises a monochromatic optical chip or is composed of a monochromatic optical chip and a phosphor layer thereon.

9. A manufacturing method of a light emitting element package structure, comprising:
disposing a plurality of light emitting chips on a bearing surface of a substrate and electrically connecting the plurality of light emitting chips to the substrate, wherein the plurality of light emitting chips compose an arrangement pattern;
forming a supporting retaining wall on the bearing surface, wherein the supporting retaining wall surrounds the plurality of light emitting chips;
injecting a diffusion glue layer in a region surrounded by the supporting retaining wall, wherein the diffusion glue layer covers the plurality of light emitting chips and the bearing surface;
forming a patterned masking colloid on the diffusion glue layer according to the arrangement pattern, so that the patterned masking colloid is located directly above the plurality of light emitting chips; and
forming a transparent protective layer in the region surrounded by the supporting retaining wall to cover the diffusion glue layer and the patterned masking colloid.

10. The manufacturing method of a light emitting element package structure according to claim 9, wherein the supporting retaining wall is formed by stacking a silicone glue material a plurality of times.

11. The manufacturing method of a light emitting element package structure according to claim 9, wherein before the patterned masking colloid is formed, a patterned retaining wall colloid is formed on the diffusion glue layer to define a limited region of the patterned masking colloid.

12. The manufacturing method of a light emitting element package structure according to claim 11, wherein the patterned masking colloid is selected from a group consisting of a black silicone glue material, and the patterned retaining wall colloid is selected from a group consisting of a white silicone glue material and a black silicone glue material.

13. The manufacturing method of a light emitting element package structure according to claim 11, wherein the patterned masking colloid, the patterned retaining wall colloid, and the supporting retaining wall use different colors of silicone glue material.

14. The manufacturing method of a light emitting element package structure according to claim 11, wherein the patterned masking colloid and the patterned retaining wall colloid are formed on the diffusion glue layer by coating, dispensing or screen printing.

15. The manufacturing method of a light emitting element package structure according to claim 11, wherein the diffusion glue layer is formed by mixing diffusion powder and a silicone glue.
